(19) United States
(12) Patent Application Publication
(10) Pub. No.: US 2014/0167190 A1
(43) Pub. Date: Jun. 19, 2014

(54) Monolithic Package for Housing Microelectromechanical Systems

(71) Applicant: Transonic Scisense Inc., London (CA)

(72) Inventors: Philip Chadwick HODGSON, Salford (CA); Peter David PLOUF, London (CA); Geoffrey Kim WOOD, London (CA); John Rene DUBOIS, III, London (CA); Anil Tharian George KOTTAM, London (CA)

(73) Assignee: Transonic Scisense Inc., London (CA)

(21) Appl. No.: 14/188,368

(22) Filed: Feb. 24, 2014

Related U.S. Application Data
(63) Continuation of application No. PCT/CA2012/050597, filed on Aug. 29, 2012.
(60) Provisional application No. 61/528,574, filed on Aug. 29, 2011.

(51) Int. Cl. B81B 7/00; B81C 3/00

(52) U.S. Cl. CPC B81B 7/0058; B81C 3/001; B81C 3/005
USPC 257/415; 438/51

(57) ABSTRACT

A sensor package for a microelectromechanical system (MEMS) is provided. The sensor package comprises a slot for receiving a MEMS, a bonding area in, or adjacent to, the slot for bonding the MEMS to the package and at least one package electrode to engage an electrode pad on the MEMS. Each package electrode is in communication with a conductor pad for connecting the MEMS to an electronic device.

### CROSS-REFERENCE TO RELATED APPLICATIONS

This application is a continuation of International PCT Application No. PCT/CA2012/050597 filed on Aug. 29, 2012, which claims priority from U.S. Provisional Patent Application No. 61/528,574, filed Aug. 29, 2011, both incorporated herein by reference

### TECHNICAL FIELD

The following relates generally to packages for housing microelectromechanical systems.

### BACKGROUND

Electromechanical sensors have been designed for a variety of purposes. For example, electromechanical sensors can be used to measure chemical concentrations, pressure, temperature, admittance, and magnetic fields. Recently, electromechancial devices, including electromechanical sensors, have been built with physical features whose dimensions measure in the micron range. These devices are known as microelectromechanical systems (MEMS). MEMS modules, including MEMS sensors, are built using fabrication methods including, for example, photolithographic and deposition techniques, adapted from very large scale integration (VLSI) semiconductor processing. Using these processes, miniaturization of electromechanical sensors has become possible.

The size reduction has also lead to a significant cost reduction per module, making MEMS sensors economical to use in a variety of applications where their larger counterparts would prove too costly. For example, on account of their miniature size, there are opportunities to use MEMS sensors, or arrays of MEMS sensors, in places that would have otherwise been inaccessible to larger sensors. Furthermore, since MEMS sensors may be orders of magnitude smaller than previously existing sensors, building arrays of these sensors, including arrays of combinations of different MEMS sensors and other MEMS modules has become economical and practical.

An example of a MEMS module is a MEMS pressure sensor. MEMS pressure sensors can, for example, be used in a catheter. A catheter may be inserted into the heart, for example, into the left ventricle, and used to measure properties such as absolute cardiac volume or to deliver a medication. The incorporation of a MEMS pressure sensor that can measure changes in blood pressure in the left ventricle allows for the mapping of the cardiac cycle and can be used to determine the blood pressure and the heart rate of the subject being tested. For example, one type of catheter that is benefitted by the addition of a pressure sensor is the admittance catheter. Admittance catheters measure the instantaneous volume of a physical lumen, for example, the left ventricle of the heart. The use of a MEMS pressure sensor in an admittance catheter would allow the cardiac cycle to be mapped by monitoring the pressure inside the left ventricle over the course of the cardiac cycle. The readings on the admittance catheter could therefore be mapped to the cardiac cycle to determine the volume of blood in the left ventricle, or any other lumen in which the catheter is installed.

### BRIEF DESCRIPTION OF THE DRAWINGS

Embodiments will now be described by way of example only with reference to the appended drawings wherein:

FIG. 1 is an example diagram of a catheter attached to a control module;

FIG. 2 is an example diagram of a catheter in a heart;

FIG. 3 is an enlarged view of the example pressure sensor assembly in the catheter;

FIG. 4 is an exploded view of the example pressure sensor assembly of FIG. 3 showing the sensor support member;

FIG. 5 is an exploded diagram of the MEMS package installed on the sensor support member;

FIG. 6 is an exploded view of the example pressure sensor assembly of FIG. 5 showing the MEMS package removed from the sensor support member;

FIG. 7 is an exploded view of the example pressure sensor assembly of FIG. 6 showing the cover membrane removed from the packaging member;

FIG. 8 is an exploded view of the example pressure sensor assembly of FIG. 7 showing the MEMS pressure sensor removed from the MEMS package;

FIG. 9 is an enlarged view of an example MEMS pressure sensor removed from a packaging member;

FIG. 10 is an enlarged view of an example MEMS pressure sensor installed in the packaging member;

FIG. 11 is an enlarged view of an example MEMS pressure sensor; and

FIG. 12 is an example flow chart outlining steps of installing a MEMS sensor a catheter.

### DETAILED DESCRIPTION OF THE DRAWINGS

It will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the example embodiments described herein may be practised without these specific details. In other instances, well-known methods, procedures and components have not been described in detail so as not to obscure the example embodiments described herein.

Also, the description is not to be considered as limiting the scope of the example embodiments described herein. For example, reference is made to the MEMS sensor package being used in the context of housing a pressure sensor in a catheter. This application is used as an example and the principles outlined herein are applicable to other MEMS modules installed in catheters. The principles outlined herein are also applicable to MEMS modules installed in other devices including, but not limited to, medical devices, mobile electronic devices, vehicle instrumentation, and other measurement instruments.

Despite the advantages of producing MEMS sensors, including a dramatic reduction in device cost and a smaller sensor size, incorporating MEMS sensors into larger assemblies remains a challenge. In particular, packaging and housing of MEMS sensors can be difficult and can significantly reduce the overall yield of functioning sensors. Packaging MEMS sensors into an assembly or a device is typically a labour intensive process. The process is also highly variable depending on the conditions and the care of the technician assembling the device. For example, the installation of pressure sensors in catheters is done by technicians using adhesives. Due to the extremely small size of the pressure sensors, the volume of adhesive required to secure the sensor in its housing may be in the nanolitre range. As this volume is far smaller than the volume of a single drop of the adhesive, it is difficult for technicians to manually dispense this volume of adhesive. Moreover, the fluid dynamic properties of the adhesive may be subject to variation depending on the ambient temperature, the relative humidity and the composition of the adhesive. Varying fluid dynamic properties may cause the volume of adhesive administered to a MEMS device to vary depending on ambient conditions. Consequently, a controlled environment is necessary to reduce the variability between devices, as even minor variations in the composition of the adhesive may alter the performance of the device.

Due to the extremely small dimensions of a MEMS sensor, which may measure less than 1 mm by 1 mm on its surface and may be only microns thick, the limits of human dexterity are approached. For example, when assembling MEMS pressure sensors into a catheter using current processes, manual labour is intensive, skilled technicians are required, and the results may be unpredictable. The placement of the sensor may be imperfect and the proper operation of the sensor may be impeded by excess adhesive or adhesive improperly placed over a portion of the sensor. The difficulty in applying adhesives to the MEMS sensor can significantly reduce the yield of the assembled devices, driving up the cost of the finished product.

In addition to the technician using adhesives to physically secure the sensor in a device, the sensor is electrically connected to a power source and an output. Typically, this is done by soldering or wire-bonding leads to the sensor. However, because of the extremely small dimensions of the sensor, wire-bonding or soldering individual leads onto electrode pads on the MEMS sensor is prone to error and may significantly reduce the yield of functional sensors in assembled devices, also driving up the cost of the finished product.

Defects in the device or variability in operation that is outside of the sensor specifications reduces the yield of the MEMS sensors through the number of devices that must be discarded or re-worked. A reduction in yield increases the cost of the devices and may negate the economic advantages of using a MEMS sensor. Furthermore, the increased variability in the devices reduces the sensitivity of the sensors and may affect overall performance of the device. Hence, packaging has become more difficult and more expensive relative to the overall cost of incorporating a sensor in a finished product. The cost of incorporating sensors into products is of importance not only from a cost-savings perspective but if a sensor can be incorporated into a device at a lower cost, lower-cost and disposable devices can benefit from the addition of sensors. Similarly, the reduction in cost per sensor may also expand the sensor market, as new applications become economically viable.

At the same time, since the MEMS sensors are significantly smaller than their larger counterparts, they have been introduced into new environments, some of which may be harsh and difficult to access, requiring that the sensor perform reliably for an extended period of time. Therefore, sensor packaging has become more critical and more prone to failure in these harsh environments. To reduce the cost of these sensors, increase reliability and broaden the number of applications where these sensors are economically viable, a more robust and more easily assembled MEMS sensor package is required.

It is therefore an object of the following to reduce the cost of sensor packaging and assembly by increasing the rate at which MEMS sensors can be installed in a device. It is a further object to reduce dependence on skilled technical labour to install MEMS sensors. It is also an object to reduce the variability in the packaging of MEMS sensors that leads to a reduction in the accuracy of the assembled sensor. It is also an object to increase the yield of assembled devices, thereby reducing the cost of finished products that incorporate MEMS sensors.

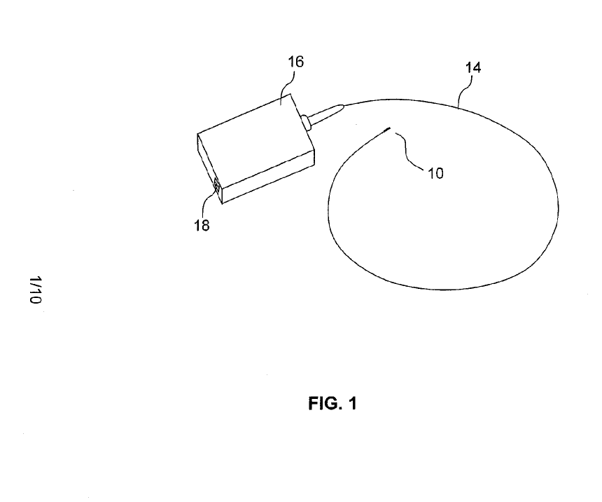

As mentioned above, one particular example use of a MEMS pressure sensor is in a catheter, for example a tetrapolar catheter, used to measure the electrical admittance in a physical lumen such as the left ventricle of the heart. By incorporating a pressure sensor in the tetrapolar catheter the cardiac cycle can be monitored, recorded, and used to determine the admittance at each point in the cardiac cycle. Referring therefore to FIG. 1, a tetrapolar catheter 10 is shown attached to a controller module (16) via connecting line 14. Connecting line 14 may comprise a hollow tube to introduce a liquid into the physical lumen and may also comprise electrical connections to power the tetrapolar catheter and the onboard pressure sensor. The connecting line 14 may also comprise data communication lines to control send and/or receive signals from the pressure sensor and the catheter electrodes. A port 18 allows information to be transferred to and from the controller module and can recharge a battery if the control module 16 comprises a battery. The length and thickness of connecting line 14 can vary depending on its use. The diameters of connecting line 14 and catheter 10 vary depending on, for example, the subject, the number of electrical connections, or the rate at which a fluid is to be delivered to the subject.

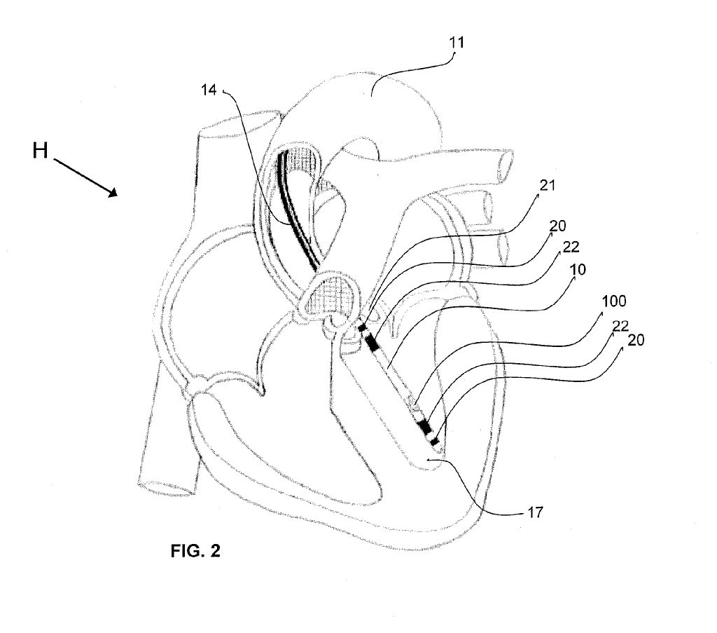

Referring now to FIG. 2, the tetrapolar catheter 10 of FIG. 1 is shown inserted into the left cardiac ventricle 17. The catheter 10 is inserted through the aorta (11) and spans the long axis of the ventricle 17. Note however that though examples shown herein are in reference to the tetrapolar catheter 10 being placed in the left ventricle 17, it will be understood that the tetrapolar catheter 10 is not limited to placement within the left ventricle 17. The same concepts could be applied to associate the admittance of the tetrapolar catheter 10 to the cardiac cycle, as measured by the pressure sensor, in any of the other three chambers of the heart in which the catheter is installed. These same concepts could also be applied to any physical lumen where tissue incursion and pressure measurements may glean insights into body functions.

The catheter 10 may comprise a first excitation electrode 20 which is placed on the upper portion of the left ventricle 17 proximal to the connecting line 14 and a second excitation electrode 20 placed at the lower portion of the left ventricle 17, at the distal end of the catheter 10. A first sensing electrode 22 is disposed adjacent to the first excitation electrode 20 and a second sensing electrode is disposed adjacent to the second excitation electrode 20 and both sensing electrodes are located between the pair of excitation electrodes 20.

Due to the placement of the electrodes, the electric field formed by the excitation electrodes 20 extends across the entire left ventricle 17. As the left ventricle 17 is composed of myocardium tissue 15, which has a different characteristic conductivity than the blood located within the ventricle 17, the electric field sensed at the sensing electrodes 22 will differ depending on the contribution from the myocardium tissue component of the conductance and the blood component of the conductance.

The catheter 10 also comprises a microelectromechanical pressure sensor assembly 100 that is sealed such that its electrical connections are isolated from the surrounding fluid medium. With a pressure sensor 100 located directly on the catheter 10, the measurements of pressure within the lumen may be made in real time. Data from the pressure sensor may be collected in real time or stored and collected from the controller 16 at a later time. The data may similarly be analyzed in real time to adjust, for example, the dispensing of a medication. By incorporating a pressure sensor directly into the left ventricle 17 where the catheter 10 is located, the pressure measurements are more accurate than those received from a pressure sensor located outside of the lumen, and much more accurate than an external blood pressure monitor. For example, if the blood pressure is measured using a sphygmomanometer, the observed variations in pressure may be significantly offset from the cardiac cycle due to the propagation delay; hence the accuracy of these measurements may be significantly impaired. Since the cardiac cycle is in the vicinity of 70 beats per minute (bpm) for a human at rest and about 550 bpm for a mouse at rest, it is important to have an accurate and responsive reading of the blood pressure of the subject being studied.

A MEMS pressure sensor installed in a catheter placed in the left ventricle can measure the subject's blood pressure of the entire cardiac cycle. Described briefly, the cardiac cycle is characterized by oxygenated blood from the lungs entering the left atrium 19, where it is delivered through the aortic valve 21 into the left ventricle 17. When the left atrium 19 has dispelled its load of blood, the left ventricle 17 contains its maximal volume of blood. At this stage, the volume of blood in the left ventricle 17 is at its maximum, which is known as the end diastolic volume (EDV). The left ventricle 17 then contracts to force the oxygenated blood through the aorta 11 to be distributed throughout the body. Blood is prevented from flowing from the left ventricle 17 to the left atrium 19 by the aortic valve 21. At the point of the cardiac cycle where the left ventricle 17 has contracted to its smallest volume, it contains only the end-systolic volume (ESV) of blood. The total volume of blood that is pumped for each contraction of the left ventricle 17 is known as the stroke volume (SV). The SV is equivalent to the difference between the end-diastolic volume and end-systolic volume of blood in the left ventricle 17.

As the volume of blood within the left ventricle 17 varies throughout the cardiac cycle, so too does the pressure within the cardiac chambers. For example, after the left ventricle 17 reaches the EDV, the myocardial tissue surrounding the left ventricle 17 contracts to force the blood through the arterial network. As a result of the compressive forces created by the contraction of the myocardial tissue surrounding the left ventricle, the pressure within the left ventricle 17 is relatively high at this point in the cardiac cycle. By measuring the pressure over the course of the cardiac cycle, it is possible to map the cardiac cycle and compare the cardiac cycle with the admittance profile. This can be done in real time, if desired, or recorded and analyzed at a later time.

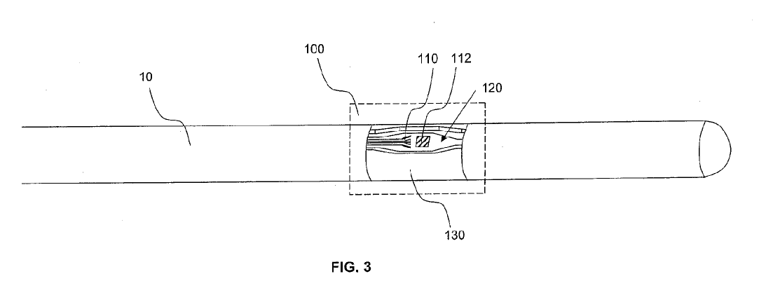

An enlarged view of a catheter 10 is shown in FIG. 3. The catheter 10 comprises a pressure sensor assembly 100, outlined by the dashed box. The sensor assembly 100 comprises a set of package electrodes 110. The package electrodes 110 may provide an electrical power source for the sensor as well as data input and output connections to transfer data. The package electrodes 110 may be electrically isolated from the surrounding fluid. A cover membrane 112 sits atop an underlying MEMS pressure sensor 160 (not shown) and may be used to physically isolate the MEMS pressure sensor from the surrounding fluids. The MEMS pressure sensor responds to pressure changes in the surrounding fluid, thus the cover membrane 112 allows for pressure changes to be transmitted to the MEMS pressure sensor.

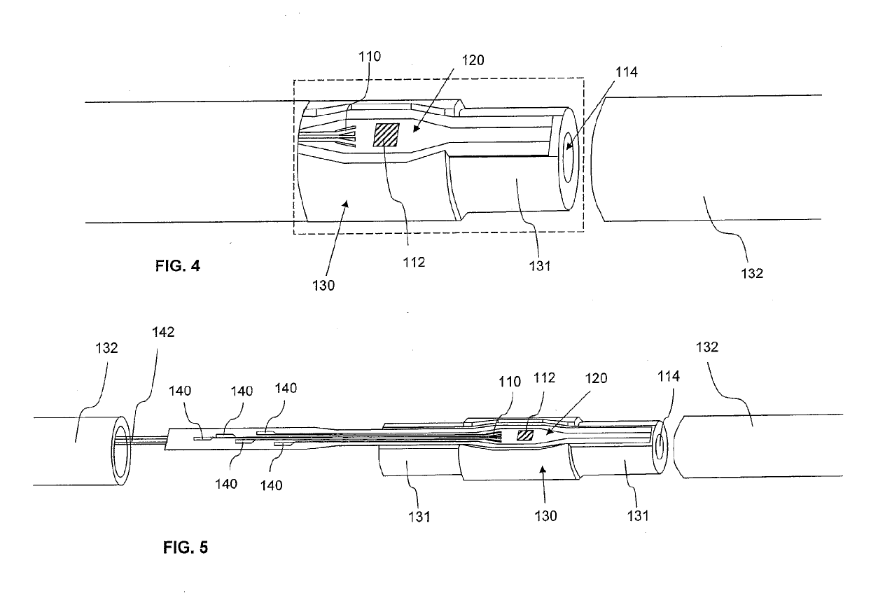

The pressure sensor assembly 100 also comprises a sensor support member 130 that is adapted to engage the catheter tubing 132. The sensor support member 130 comprises a sensor window 150. The catheter 10 may be produced from tubing with a length and diameter dependent on the dimensions of the lumen in which it is designed to probe. The sensor support member 130 has a fitting 131 that is adapted to engage with the catheter tubing 132. For example, a fitting 131 may be located on each end of the sensor support member 130 and may be of a form that is complementary to the catheter tubing 132, and adapted to couple with the catheter tubing 132. An example fitting 131 on the distal end of the sensor support member 130 is shown in FIG. 4. For example, the fitting adapted to couple with the catheter tubing 132 may comprise a quick connect fitting or a luer fitting. The catheter tubing 132 may additionally be secured to the sensor support member 130 using an adhesive on the fitting. The catheter tubing 132 may be cylindrical, or any other geometry that can accommodate a pressure sensor and be inserted into the physical lumen that is to be probed.

The sensor support member 130 comprises a through passage 114 that can accommodate electrical connectors for the pressure sensor and any other sensors or devices on the distal end of the catheter 10. The sensor window 150 in the sensor support member 130 extends from the through passage 114 to the ambient fluid. The through passage 114 may allow passage of a fluid that can be used to deliver a liquid, for example, a medication. The through passage 114 may be adapted to provide a reference pressure for the pressure sensor. The reference pressure may be a tubing connection through the catheter 10 and the connecting line 14 with the ambient air to allow the pressure sensor to deliver readings that are relative to the ambient barometric pressure.

Turning to FIG. 5, the sensor support member 130 is shown disassembled from the catheter tubing 132. The entire upper surface of a MEMS package 120 is visible, showing a number of conductor pads 140 electrically contacting the package electrodes 110 on the MEMS package 120. The MEMS package 120 provides a housing for the MEMS sensor that physically supports the sensor and provides electrical connections to the electrodes on that sensor. The MEMS package 120 may be formed using various methods including photolithographic techniques, laser cutting, or die stamping. Photolithography is particularly well-suited to small MEMS modules, as feature sizes can be made to be smaller and more defined than those achieved using mechanical die stamping or laser cutting processes. The conductor pads 140, package electrodes 110 and the conductors that run therebetween may be deposited directly on the surface of the MEMS package 120. The conductors, as well as the package electrodes 110 and the conductor pads 140 may be single-layer structures or may be multi-layer structures to accommodate more complex circuitry, particularly in cases where the MEMS package 120 accommodates a plurality of MEMS.

The electrical conductors may be made from various conductive materials, for example, metals such as gold or aluminum. The conductors may also be formed from multiple layers of different metals, for example, a copper-nickel-gold stack. The thicknesses of the electrical conductors may be set based on electrical requirements as well as physical rigidity requirements of the MEMS package 120. The conductors may also be arranged in a winding pattern such that they are more compliant if some flexibility is desired in the MEMS package 120. The MEMS package 120 may be made from a polymer such as a polyimide. For example, poly(4,4′-oxydiphenylene-pyromellitimide), which is known commercially as Kapton, can remain stable at higher temperatures than most polymers, which is helpful in deposition processes. Kapton is also a biocompatible polymer that is currently used in implantable devices and is relatively impermeable to gas, and so would minimize the transfer of gases through the MEMS package 120. The dimensions of the MEMS package 120 may be chosen based on rigidity requirements. The MEMS package 120 may also be reinforced using other materials, for example, ceramics, metals and/or other polymers (e.g. polysulfone).

The MEMS package 120 may be retained in a complementary groove in the sensor support member 130 and may additionally be held in place by a slot, a collar and/or an adhesive. The MEMS pressure sensor 160 is aligned with the sensor window 150 in the sensor support member 130. The conductor pads 140 may each receive a conductor wire 142 that is in communication with the controller 16 through the communication line 14. The conductor pads 140 may be in electrical contact with the conductor wire 142 through, for example, a soldering connection, a removable fitting, or wire bonding. The conductor wire 142 may extend through the communication line 14 to connect directly with the controller 16 or may connect with a conductor in the communication line 14. The conductor wires 142 may, for example, be inserted into receptacles adapted to receive the conductor wires 142 on the underside of the MEMS package 120. The conductor pads 140 are more spaced apart than the electrodes on the MEMS pressure sensor and due to their larger scale, far easier to connect with conductor wires 142.

To install the MEMS package 120 fixed to the sensor support member 130 into the catheter 10, the conductor wires 142 may be inserted into slots in the conductor pads 140. The insertion of conductor wires 142 may be done by a technician or a machine. Once the conductor wires 142 are installed, the catheter tubing 132 can be coupled with the fittings 131 on the sensor support member. The conductor wires 142 may extend through the catheter 10 and engage with the connecting line 14. The conductor wires 142 may also extend through the connecting line and engage directly with electrical contacts on the controller 16. By having a MEMS package 120, the conductor wires 142 can more easily be routed to the MEMS sensor and the MEMS package 120 comprising the MEMS sensor can be placed in the catheter 10 with a much lower chance of assembly error due to misplaced adhesive or improperly bonded solder.

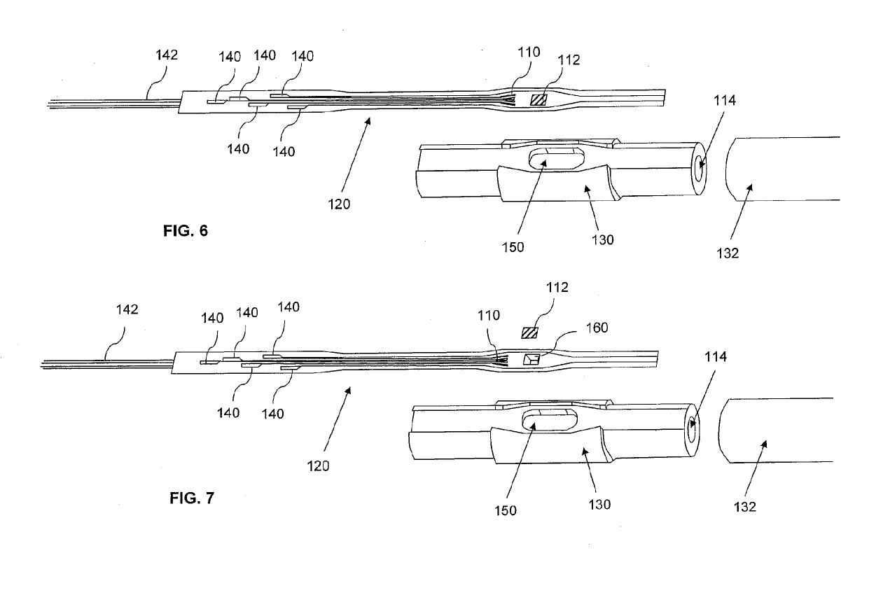

The MEMS package 120 is shown removed from the sensor support member 130 in FIG. 6. The MEMS package 120 comprising the cover membrane 112, MEMS pressure sensor 160, the package electrodes 110 and the conductor pads 140, remains in contact with the conductor wires 142. Beneath the MEMS pressure sensor 160 (not shown) lies a slot 170 that may comprise, for example, a recess with a resilient and elastic membrane, or a cavity that extends to the through passage 114. The slot 170 can be used to provide a reference to an external pressure outside of the catheter 10 through the catheter tubing 132 and the connecting line 14.

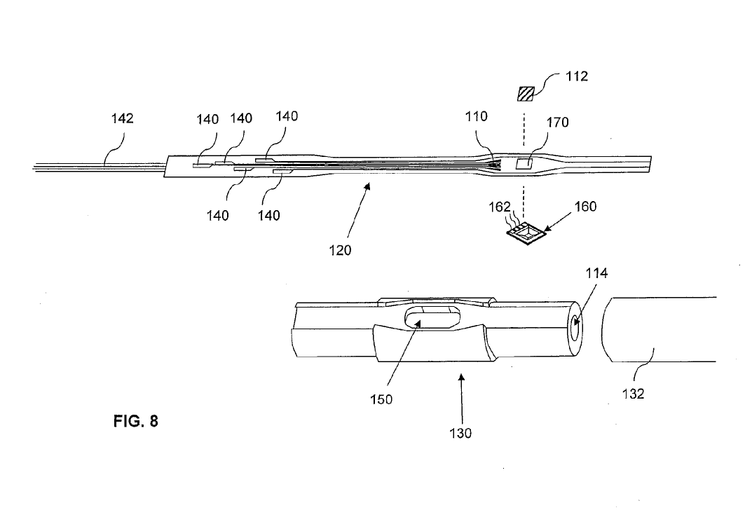

Beneath the cover membrane 112 lays the MEMS pressure sensor 160, as shown in FIG. 7. The MEMS pressure sensor 160 sits in a sensor slot 170 (not shown) or on the MEMS package 120 and is bonded to a bonding area in the proximity of the slot 170. The physical dimensions of the slot 170 define a repeatable thickness of material over the membrane of the MEMS pressure sensor 160. The MEMS pressure sensor 160 may be bonded to the underside of the MEMS package 120. The cover membrane 112 may be optional and is used where needed to physically isolate the MEMS pressure sensor 160 from the ambient fluid without appreciably attenuating the pressure signal. The MEMS pressure sensor 160 is shown removed from the underside of the MEMS package 120 in FIG. 8. The MEMS pressure sensor 160 comprises electrode pads 162 that come into contact with the package electrodes 110 on the underside of the MEMS pressure sensor 160 when the MEMS pressure sensor 160 is installed. The electrical contacts between the MEMS electrode pads 162 and the package electrodes 110 enable electrical communication between the electrode pads 162 in the MEMS sensor and the conductor pads at the distal end of the MEMS package 120. The MEMS electrode pads 162 and the package electrodes 110 may be connected, as described above, via soldering, wire bonding or any other electrical connection method. This enables signals and electrical power to be transmitted between the controller 16 and the MEMS pressure sensor 160 through the connecting line 14, the conductor wires 142 and the MEMS package 120.

The assembly of the MEMS pressure sensor 160 into the MEMS package 120 is more easily accomplished, as there is a defined sensor slot 170 in which the MEMS pressure sensor 160 may be secured. The MEMS package 120 is further provided with pre-fabricated package electrodes 110, which obviate the need for electrical connectors to be manually and individually wired to the electrode pads 162 on the MEMS pressure sensor 160. For installation, the MEMS pressure sensor 160 may, for example, be placed in the sensor slot 170 and the electrode pads 162 may be bonded to the package electrodes 110 using, for example, a reflow solder step or wire-bonding techniques. The MEMS pressure sensor 160 may also be adhered to the inner faces of the slot 170 using, for example, an adhesive or using solder, which can be reflowed to bond the MEMS pressure sensor 160 to the inside faces of the slot 170 without impacting the operation of the MEMS pressure sensor 160. The MEMS pressure sensor 160 may be bonded in the slot 170 or on the surface of the MEMS package 120 around the slot 170 in the same reflow step as the electrode pad 162 solder reflow step. This provides a much easier method of connecting electrode pads 162 to the MEMS pressure sensor 160, since the MEMS pressure sensor 160 is retained at the sensor slot 170 and the electrode pads 162 are aligned with the package electrodes 110. Moreover, this method may be a much quicker processing step as the electrode pads 162 can be bonded to the package electrodes 110 simultaneously. The MEMS pressure sensor 160 may also be durably secured inside or on the surface surrounding the slot 170, preventing the transmission of gases or other fluids between the MEMS pressure sensor 160 and the slot 170.

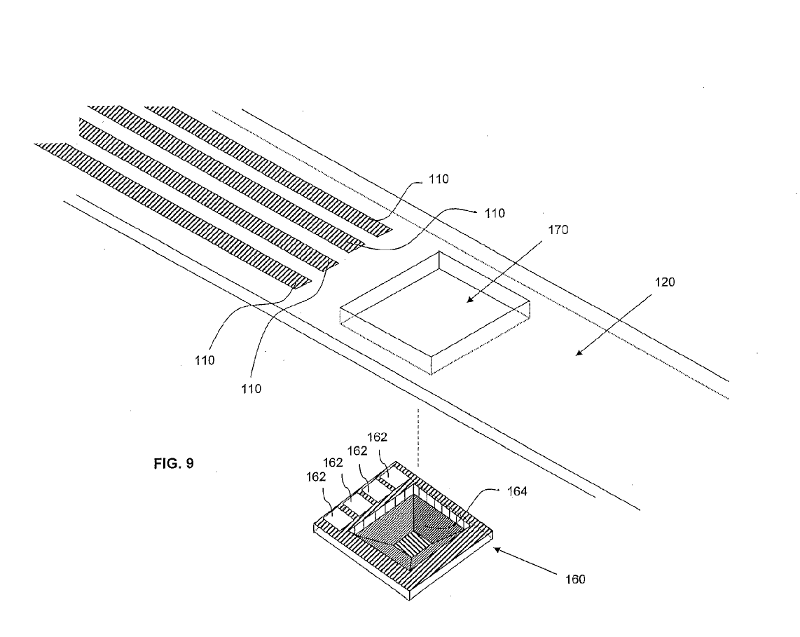

An enlarged view of a MEMS package 120 and a MEMS pressure sensor 160 shown in FIG. 9 illustrates the placement of the electrode pads 162 on the MEMS pressure sensor 160 and additionally, shows the layout of the package electrodes 110 on the MEMS package 120. The MEMS pressure sensor 160 may be placed in or at the slot 170 with the sensing area 164 oriented such that it is subject to pressure changes in the ambient fluid. The slot 170 and MEMS pressure sensor 160 may optionally be designed such that there is only one orientation that allows for the MEMS pressure sensor 160 to be placed in or at the slot 170. This design may significantly reduce the likelihood that the MEMS pressure sensor 160 is improperly installed and also reduce the likelihood that the package electrodes 110 are improperly bonded to the sensor electrodes 162. Each MEMS package 120 may also be provided with a plurality of MEMS mounting points. For example, the MEMS package 120 may be provided with mounting points for an array of MEMS, which may include one or more MEMS pressure sensors 160.

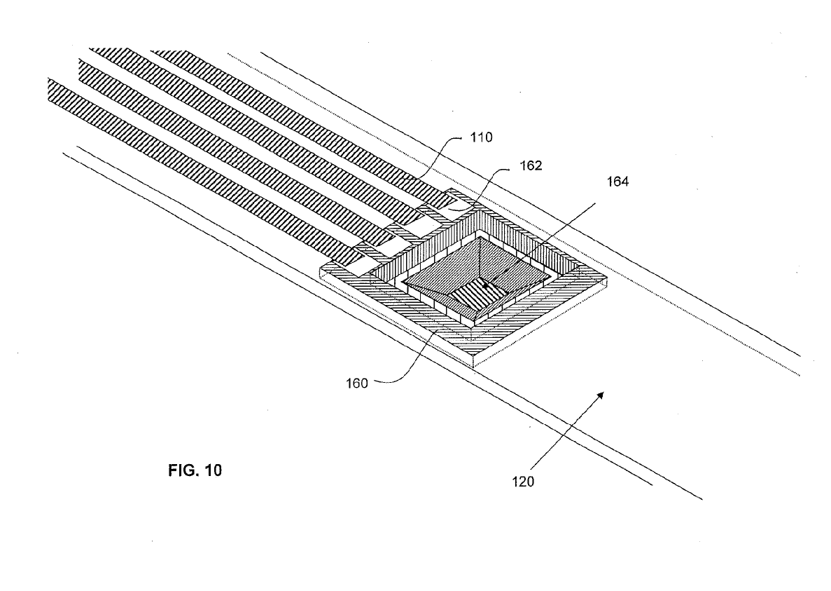

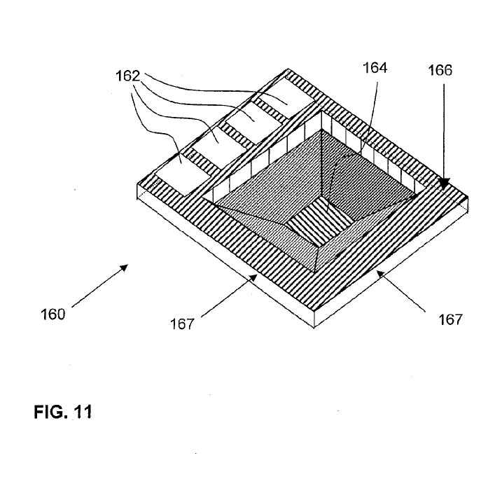

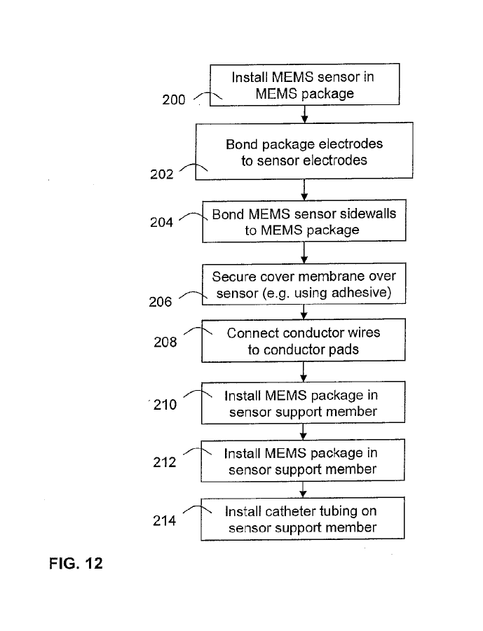

Once the MEMS pressure sensor 160 is fitted into the slot 170, the package electrodes 110 are in electrical contact with the sensor electrodes 162, as shown in FIG. 10. As also shown in FIG. 10, the MEMS pressure sensor 160 can be installed from below the MEMS package 120 and may be sealed to the MEMS package 120 around the slot 170 via an adhesive or a metallic bond, for example, a solder bond. For example, if the bond is achieved using a solder reflow method, the solder may be deposited on the MEMS pressure sensor 160 or on the MEMS package 120 or on both and heated when the MEMS pressure sensor 160 is in position. Solder may also be placed on the package electrodes 110 or on the sensor electrodes 162 to simultaneously reflow solder the electrical connections.

As mentioned above, the electrical connections may also be formed prior to, or after, the MEMS pressure sensor 160 is bonded to the MEMS package. The MEMS package 120 and MEMS pressure sensor 160 may then be heated using, for example, infrared radiation, a reflow oven or a hot air pencil. The process may comprise, for example, controllably heating the solder to its melting temperature, maintaining this temperature for a period of time, applying a measure of pressure to keep the MEMS pressure sensor 160 located directly in position and to ensure good contact, and then controllably cooling to MEMS package 120 and MEMS pressure sensor 160. This process can be performed manually, by a machine, or in an automated process such as reel-to-reel assembly. For example, the MEMS pressure sensors 160 could be placed on the MEMS package 120 using a wheel that releases a single MEMS pressure sensor 160 from a film containing a plurality of spaced MEMS sensors over the slot in each MEMS package 120. The MEMS package 120 may also accommodate, for example, more than one MEMS pressure sensor 160 or various other MEMS sensors. If the MEMS package 120 accommodates a plurality of sensors, an automated assembly process offers a more significant benefit, as the labour savings may be amplified.

The bonding material that secures the MEMS pressure sensor 160 to the MEMS package 120 may be placed on the MEMS pressure sensor 160 during manufacture. The bonding material may equally be placed on the MEMS package 120. The bonding material may be placed on the upper surface 166 of the MEMS pressure sensor 160, which also comprises the sensor electrodes 162. To prevent a short circuit, particularly with a conductive bonding material, a spacing may exist between the sensor electrodes 162 and the bonding material on the surface 166 of the MEMS pressure sensor 160. If the MEMS pressure sensor 160 is placed inside the slot 170, the bonding material may be placed on the sides 167 of the MEMS pressure sensor 160. Using pre-placed bonding material, particularly a bonding material that can be deposited during the MEMS pressure sensor 160 fabrication procedure or during the MEMS package 120 fabrication procedure, reduces the likelihood that the bonding material will reach the sensing area 164.

The process of installing a MEMS pressure sensor 160 into a finished device can vary depending on the materials and equipment used. An example of a procedure for assembling a MEMS pressure sensor 160 into a tetrapolar catheter 10 using the MEMS package 120 described above is outlined in FIG. 11. It will be appreciated that the steps outlined below may be performed sequentially, in parallel, or may be performed out of sequence and the exact procedures used may differ from those described without departing from the scope of the principles described herein. The MEMS pressure sensor 160 is first positioned on the MEMS package 120 such that the sensor electrodes 162 align with the package electrodes 110. The MEMS pressure sensor 160 may be in a housing that provides external sensor electrodes 162 or the MEMS pressure sensor 160 may bond directly to the package electrodes 110 at the MEMS wafer level. In step 202, the package electrodes 110 are bonded to the sensor electrodes 162. In step 204, the MEMS pressure sensor 160 is then bonded to the MEMS package 120. These steps may be done in any order or may also be done concurrently, particularly when the bonds comprise a solder reflow which may be accomplished using a heating step. Once the MEMS pressure sensor 160 is bonded and electrically connected to the MEMS package 120, the cover membrane is secured over the sensor in step 206. The cover membrane 112 may be secured using, for example, adhesive or a solder reflow procedure. The conductor wires 142 may be connected to the conductor pads 140 on the MEMS package 120 in step 208. The MEMS package 120 comprising the MEMS pressure sensor 160 and the cover membrane 112 may be installed in the sensor support member 130 in step 210. The conductor wires 142 may also be attached after the MEMS package 120 has been installed in the sensor support member 130. The MEMS package 120 may be sealed to the sensor support member 130 using an adhesive. In step 212, the catheter tubing 132 is installed on fittings 131 located on the sensor support member 130. The fittings 131 may also be sealed with an adhesive. The catheter 10 may then be completed by installing the connecting line 14 and sealing the catheter tubing 132 to prevent fluid ingress.

Several advantages are realized by using a MEMS package 120 to install a MEMS pressure sensor 160 in a catheter. The cost of sensor packaging is reduced, as the MEMS pressure sensor 160 may be installed in the MEMS package 120 in less time and this may be accomplished using an automated process. The cost is further reduced by simplifying the physical support of the MEMS pressure sensor as well as the electrical connections to the sensor electrodes, reducing the number of defective devices employing MEMS sensors. Furthermore, by bonding the electrical connections in a single solder reflow procedure, each MEMS sensor can be installed in the MEMS package 120 more quickly and with fewer defects than through a manual installation. Since the MEMS pressure sensors 160 may be installed in the MEMS package 120 using an automated process, the dependence on skilled technical labour to manually install each MEMS pressure sensor 160 is reduced. Variability in the devices is also reduced since the bonding material (e.g. solder, metal, or adhesive) may be deposited on the MEMS pressure sensor 160 and/or on the MEMS package 120 and hence, doesn't require manual dispensing. This improvement in procedure would also mitigate many of the fluid dynamic effects on the adhesive due to variability in the ambient pressure, humidity and temperature. From the advantages including higher yield, a potentially automated process, reduced cost and reduced variability, the method of installing a MEMS pressure sensor 160 in a catheter 10 as described herein has significant apparent advantages.

Many of these advantages realized using a MEMS package 120 to install a MEMS pressure sensor 160 in a catheter 10 are also realized when installing other MEMS modules in other devices. For example, a MEMS pressure sensor 160 or other MEMS may be embedded in the side of a needle. The advantages could, for example, also be realized when installing an array of sensors in a mobile device, for example, a smartphone or personal navigation equipment. Similar advantages could be realized when installing MEMS modules in passenger vehicles, unmanned vehicles or components of vehicles. Moreover, because the use of the MEMS package 120 reduces the costs associated with packaging MEMS modules, MEMS modules may be economically viable on a broader range of devices. For instance, where a pressure sensor may not have been economically viable to include in a mobile navigation device if each of the electrical connections had to be individually installed, the incorporation of a MEMS pressure sensor in a mobile navigation device may be economically viable in a mobile navigation device when installed using a MEMS package.

Although the above has been described with reference to certain specific example embodiments, various modifications thereof will be apparent to those skilled in the art without departing from the scope of the claims appended hereto.

1. A sensor package for a microelectromechanical system (MEMS) comprising:
a slot for receiving a MEMS;
a bonding area in, or adjacent to, the slot for bonding the MEMS to the package; and
at least one package electrode to engage an electrode pad on the MEMS, each package electrode being in communication with a conductor pad for connecting the MEMS to an electronic device.

2. The package of claim 1 further comprising a cover membrane to physically isolate the MEMS from ambient fluid.

3. The package of claim 1 further comprising a sensor support member to support the sensor package, the sensor support member having a sensor window aligned with the MEMS.

4. The package of claim 3 wherein the package is installed in a catheter.

5. A method of installing a microelectromechanical system (MEMS) comprising:
obtaining a sensor package comprising a slot for receiving a MEMS, a bonding area in, or adjacent to, the slot for bonding the MEMS to the package, at least one package electrode to engage an electrode pad on the MEMS, and a conductor pad in communication with each of the at least one package electrodes to connect the MEMS to an electronic device;
bonding the MEMS to the bonding area on the sensor package; and
connecting an electrode pad on the MEMS to a package electrode on the sensor package.

6. The method of claim 5 further comprising:
obtaining a sensor support member comprising a sensor window and two ends;
aligning the MEMS on the sensor package with the sensor window;
fitting catheter tubing to the ends of the sensor support member; and
connecting the conductor pads to a control module.
